(19) United States
(12) Patent Application Publication
(10) Pub. No.: US 2023/0153181 A1
(43) Pub. Date: May 18, 2023

(54) ELECTRONIC DEVICE WITH PREDETERMINED COMPRESSION SCHEMES FOR PARALLEL COMPUTING

(71) Applicant: Samsung Electronics Co., Ltd., Suwon-si (KR)

(72) Inventors: Se Hyun YANG, Seongnam-si (KR); Sungju RYU, Goyang-si (KR); Ho Young KIM, Suwon-si (KR)

(73) Assignee: Samsung Electronics Co., Ltd., Suwon-si (KR)

(21) Appl. No.: 17/896,788

(22) Filed: Aug. 26, 2022

(30) Foreign Application Priority Data
Nov. 15, 2021 (KR) 10-2021-0156626

(51) Int. Cl. G06F 9/54; G06F 9/52; G06N 5/04

(52) U.S. Cl. CPC G06F 9/543; G06F 9/52; G06N 5/04

(57) ABSTRACT

Disclosed are electronic devices with predetermined compression schemes for parallel computing and methods thereof. An example electronic device includes cores of one or more processors, one or more memories storing instructions configured to, when executed by the cores, configure the cores to perform operations of an application executed on the electronic device, the operations including communication phases that communicate data between the cores, wherein the application includes, prior to execution of the application on the electronic device, predetermined information associating the communication phases with respective compression schemes, and apply the compression schemes corresponding to the communication phases according to the predetermined information to compress the data of the communication phases that is exchanged between the cores when executing the application.

### CROSS-REFERENCE TO RELATED APPLICATIONS

This application claims the benefit under 35 USC § 119(a) of Korean Patent Application No. 10-2021-0156626, filed on Nov. 15, 2021, in the Korean Intellectual Property Office, the entire disclosure of which is incorporated herein by reference for all purposes.

### BACKGROUND

### 1. Field

The following disclosure relates to an electronic device with predetermined compression schemes for parallel computing.

### 2. Description of Related Art

To quickly execute an application involving large-scale operations, the application may be executed in parallel by many processors. As the number of processors employed for a given tasks increases, the total amount of related data communicated between the processors may significantly increase. That is, large-scale parallel execution of a task may be accompanied by a significant increase in the amount of communication data, which may bring a significant performance drop.

### SUMMARY

In one general aspect, an electronic device includes cores of one or more processors, one or more memories storing instructions configured to, when executed by the cores, configure the cores to perform operations of an application executed on the electronic device, the operations including communication phases that communicate data between the cores, wherein the application includes, prior to execution of the application on the electronic device, predetermined information associating the communication phases with respective compression schemes, and apply the compression schemes corresponding to the communication phases according to the predetermined information to compress the data of the communication phases that is exchanged between the cores when executing the application.

The predetermined information may be generated, before the execution of the application, based on determining dominant data patterns of the communication phases while analyzing the application before the application is executed.

The cores may comprise a source core and a destination core located in a same processor, in different processors, or in processors comprised in different electronic devices.

The application may include a molecular dynamics (MD) simulation, training of and/or inference by an artificial intelligence module, supercomputer-based processing, and/or a multi-node task.

The application may perform an MD simulation, wherein a first of the compression schemes is associated, by the predetermined information, with communication phases that communicate coordinate data of simulated atoms between the cores, the first compression scheme including a block floating point-based compression scheme, and wherein a second of the compression schemes may be associated, by the predetermined information, with communication phases that communicate data of force data of the simulated atoms between the cores, the second compression scheme including a zero-value-aware-based compression scheme.

The one or more processors may include any one or any combination of: a central processing unit (CPU), a graphics processing unit (GPU), or a neural processing unit (NPU).

The predetermined information may indicate which communication phases are associated with which compression schemes.

The predetermined information may be generated by, prior to the executing of the application on the electronic device, analyzing data communicated between the communication phases to identify patterns of the data.

In one general aspect, a method includes executing an application in parallel on cores of an electronic device, including executing communication phases on the cores, wherein, prior to beginning the executing of the application, the communication phases are associated with compression schemes, and wherein which communication phases are associated with which compression schemes is determined, prior to the beginning the executing of the application, by analyzing data patterns of the communication phases and based thereon associating the communication schemes with the communication phases, and when executing each of the communication phases, checking, for each of the communication phases, for a compression scheme pre-associated therewith, and based thereon, communicating data of the communication phases between the cores using compression and decompression of the pre-associated compression schemes.

An association between a compression scheme and a communication phase may be predetermined based on determining a dominant data pattern of the communication phase in an analysis procedure performed for the application before the executing of the application.

The cores may perform the compression and decompression and may be located either in a same processor or in different processors.

The electronic device may include two computing devices, the computing devices including respective processors, the processors each including a respective one of the cores.

A second electronic device may include a second core, wherein the executing the application may further include executing the application on the second core, and when executing a communication phase on the second core, checking, for a compression scheme pre-associated with the communication phase executing on the second core, and based thereon, communicating data of the communication phase executing on the second core between the second core and a core of the electronic device using compression and decompression of the pre-associated compression schemes.

The application may include a molecular dynamics (MD) simulation.

The application may train or implement a machine learning model.

The application may implement an MD simulation, wherein a first of the compression schemes may include a block floating point-based compression scheme, and wherein a second of the compression schemes may include a zero-value-aware-based compression scheme.

The electronic device may include a central processing unit (CPU) including one or more of the cores, a graphics processing unit (GPU) including one or more of the cores, and/or a neural processing unit (NPU) including one or more of the cores.

In one general aspect, a method includes executing an application in parallel on two cores, the application including operation phases and communication phases, the operation phases generating data, the communication phases exchanging the data between the cores, the application further including, prior to execution of the application, association information including first association information associating first of the communication phases with a first compression scheme and second association information associating second of the communication phases with a second compression scheme. The method further includes, when executing a first communication phase, based on the first association information, using the first compression scheme to compress and decompress data exchanged between the cores by the first communication phase, and when executing a second communication phase, based on the second association information, using the second compression scheme to compress and decompress data exchanged between the cores by the second communication phase.

The method may further include, before executing the application on the two cores, identifying patterns of data associated with the communication phases, and generating the association information based on the identifying of the patterns.

A first identified pattern of data may correspond to the first communication phases and a second identified pattern of data may correspond to the second communication phases.

The identifying may include determining a most frequent or common pattern of data associated with a communication phase and wherein the generating the association information may include associating a compression scheme with the communication phase based on the pattern of data determined to be most frequent or most common.

In one general aspect, a non-transitory computer-readable storage medium stores instructions that, when executed by a processor, cause the processor to perform any of the methods.

Other features and aspects will be apparent from the following detailed description, the drawings, and the claims.

### BRIEF DESCRIPTION OF THE DRAWINGS

FIG. 1 illustrates an example of an electronic device configured to execute an application, according to one or more embodiments.

FIG. 2 illustrates an example of an analysis procedure and a runtime procedure, according to one or more embodiments.

FIG. 3 illustrates an example of performing a molecular dynamics (MD) simulation by dividing the simulation into a plurality of domains, according to one or more embodiments.

FIG. 4 illustrates an example of determining a compression scheme for coordinate data in an MD simulation, according to one or more embodiments.

FIG. 5 illustrates an example of determining a compression scheme for force data in an MD simulation, according to one or more embodiments.

FIG. 6 illustrates an example of a hybrid compression scheme applied at runtime of an MD simulation, according to one or more embodiments.

FIG. 7 illustrates an example of an operating method of an electronic device, according to one or more embodiments.

Throughout the drawings and the detailed description, unless otherwise described or provided, the same drawing reference numerals will be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

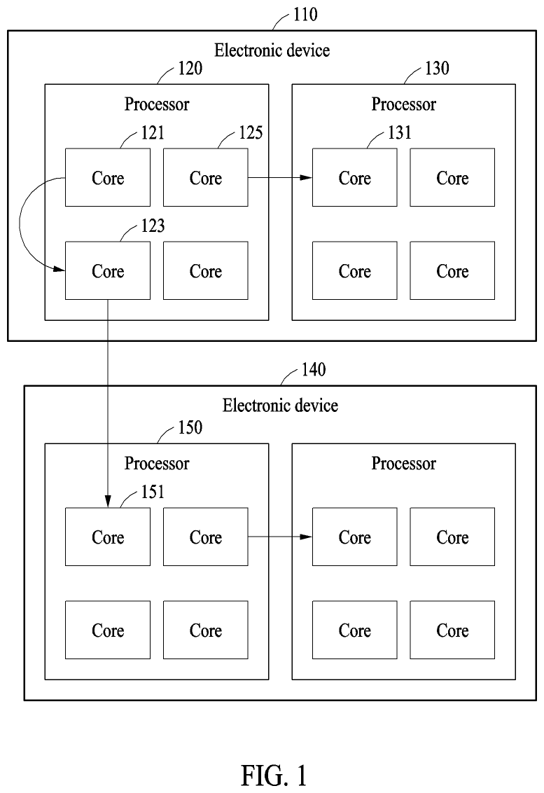

FIG. 1 illustrates an example of an electronic device 110 for executing an application, according to one or more embodiments. The electronic device 110 may include one or more processors, and each processor may include one or more cores. The electronic device 110 is illustrated as an example of a device for performing a parallel operation task (e.g., of an application), and the parallel operation task may be performed by the electronic device 110 cooperating with an electronic device 140, depending on implementation. Regarding FIG. 1, the number of electronic devices, processors, and/or cores for performing the parallel operation task can vary depending on the implementation.

A parallel operation task may include computation phases and communication phases. Using many cores, processors, and/or electronic devices in order to quickly perform a potentially large-scale parallel operation task may reduce the duration of the computation phase, however, this may increase an amount of data from the computation phase that may need to be moved within the electronic device 110 (e.g., between cores) during the following communication phase and therefore may increase the amount of time needed to move the data.

The amount of data moved between cores during a communication phase may be reduced by compressing the data thereof. Although, for optimization, a compression scheme for this purpose may be selected based on a pattern of the data to be moved (i.e., compression-related features of the data), it may be inefficient to determine patterns of the data and select a compression scheme suitable therefor in real time at runtime.

It is possible to reduce working time and improve overall performance by (i) predetermining compression schemes appropriate to respective data patterns based on analysis of the patterns of data moving between cores during a pre-runtime analysis procedure and then, (ii) at runtime, statically applying the predetermined compression schemes to corresponding data at runtime.

Data may move from one core to another core in up to three different ways. First, data may move between cores (e.g., from a core 121 to a core 123) included in a same processor 120. Next, data may move between cores (e.g., from a core 125 to a core 131) in different processors (e.g., processors 120 and 130) in the same electronic device. Finally, data may move between cores (e.g., from the core 123 to a core 151) included in different electronic devices (e.g., electronic devices 110 and 140). The core 151 may be included in a processor 150 of the electronic device 140. Data compression techniques described herein may apply to each of the three types of inter-core data movement described above.

A processor is a device for performing various data processing and/or operations. For example, the processor may include a central processing unit (CPU), a graphics processing unit (GPU), and/or a neural processing unit (NPU), and/or processing circuitry of the same, as nonlimiting examples.

An electronic device may be, for example, any of various computing devices such as a mobile phone, a smart phone, a tablet PC, an e-book device, a laptop computer, a personal computer (PC), a supercomputer, a server, a wearable device (e.g., a smart watch, smart eyeglasses, a head mounted display (HMD), or smart clothes) a home appliance (e.g., a smart speaker, a smart television (TV), or a smart refrigerator), a smart vehicle, a smart kiosk, an Internet of things (IoT) device, a walking assistance device (WAD), a drone, a robot, or the like, as nonlimiting examples.

The large-scale parallel operation task may be, for example, an application including any one or any combination of molecular dynamics (MD) simulation, training and/or inference of artificial intelligence (i.e., training and/or using a machine learning model), supercomputer-based processing (e.g., weather modeling), a multi-node task, etc., as non-limiting examples.

Described herein are data compression techniques for reducing the amount of data moving between cores while performing potentially large-scale parallel operation tasks.

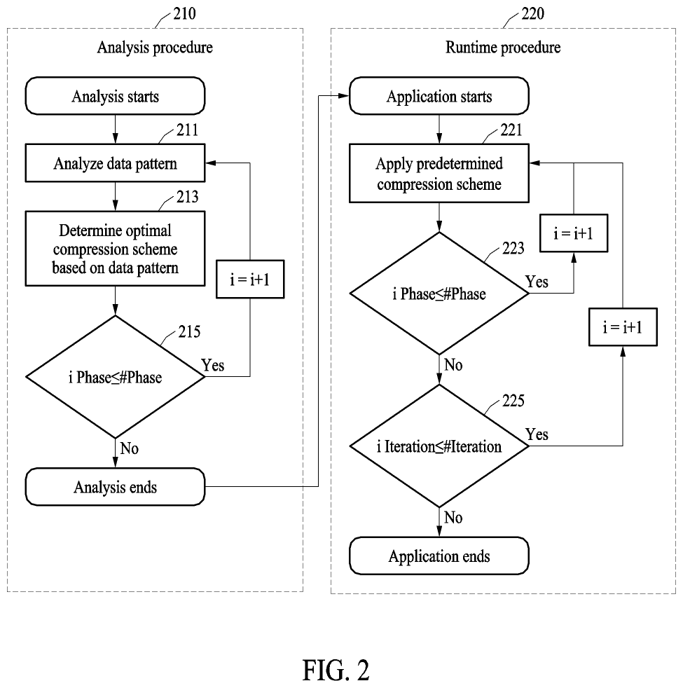

FIG. 2 illustrates an example of an analysis procedure 210 and a runtime procedure 220, according to one or more embodiments. The analysis procedure 210 may be used for analysis of operating phases of an application before the application is executed based on the analysis The runtime procedure 220 may be used for when the application is executed after the analysis procedure 210.

In operation 211 of the analysis procedure 210, pattern analysis may be performed for an application. The application may have operating phases that include communication phases, and some of the communication phases may have their own patterns of data movement, that is, different communication phases may move data with different data patterns. An electronic device may analyze each of one or more communication phases of the application to attempt to detect (identify, determine, recognize, etc.) a pattern of data moving at each of the communication phases. The electronic device may analyze the data being moved for a given communication phase to identify a dominant data pattern of the given communication phase. For example, the electronic device may analyze whether common values are included in the data moving between cores (e.g., when a dictionary compression might be appropriate) or whether “0”s are common or predominant in the data moving between cores.

In operation 213, the electronic device may determine optimal compression schemes for the communication phases based on the data patterns identified for the respective phases. The operation 213 may be configured with instructions that implement logic that associates different data patterns with respective different compression schemes. Or, the operation 213 may lookup such associations in an external table mapping data patterns to compression schemes. For example, with respect to a communication phase during which the analysis determines that common values are included in multiple data items of the communication phase (perhaps above a threshold occurrence rate), the electronic device may select a block floating point-based compression scheme that bundles common values and expresses the common values as a block form. For a communication phase during which analysis identifies many “0”s in the communicated data (e.g., above a threshold frequency or average length), the electronic device may select a zero-value-aware-based compression scheme that compresses the values of “0”. Any known compression scheme may be used and embodiments described herein are not limited to the above examples. Any compression scheme appropriate to any discernible data pattern determined to be the dominant or most common data pattern of that communication phase may be selected. An appropriate compression scheme may be determined based on additional and/or other factors, such as overhead of compression, predicted overall compression rate (some communication phases may not have enough benefit from compression to justify the computation overhead), etc. In some embodiments, corresponding code of the application (e.g., compiler hints, types of operations being performed in parallel, etc.) may be analyzed to inform operation 213's determination of an appropriate compression scheme.

In operation 215, the electronic device may determine whether there is a phase during which data pattern analysis and compression scheme determination/selection has not performed yet. While any phase remains to be analyzed, the electronic device may perform operations 211 and 213 described above for the corresponding phase. Conversely, when data pattern analysis and compression scheme determination have been performed for all phases, the analysis procedure 210 may end, associations between communication phases and respective compression schemes may be stored in association with the application, etc.

In operation 221 of the runtime procedure 220 for running the application, the electronic device (or another) may execute the application and while doing so apply compression schemes predetermined, as described above, to be associated with each of the one or more phases having communication between cores (the application may have other phases of operation, e.g., computation phases). For example, the electronic device performing the runtime procedure 220 of executing the application may apply a block floating-point-based compression scheme to any communication phases during which the analysis determined that common values are included in multiple data and may apply a zero-value-aware-based compression scheme to any communication phases during which analysis determined that “0”s are included in the data in sufficient quantity or frequency.

In operation 223, the electronic device may determine whether all the operating phases for the application have been performed. If there is an unperformed phase, the electronic device may perform operation 221 for the corresponding phase. Conversely, when all the operating phases for the application have been performed, operation 225 may be performed consecutively.

In operation 225, the electronic device may perform the application one or more times in an example. If additional execution of the application is required, the preceding operations 221 and 223 may be performed. When the execution of the application is completed, the runtime procedure 220 may end.

As such, in the runtime procedure 220, a compression scheme may not need to be determined on-the-fly (although on-the-fly and pre-determined compression selection may both be used). Instead, the compression schemes predetermined in the analysis procedure 210 may be used without being changed (for their respective phases). That is, the compression schemes may be statically allocated in advance to each operation phase before the operation phase starts. As a result, an amount of inter-core communication data may be effectively reduced and the overhead of complicated on-the-fly compression scheme searching may not be necessary.

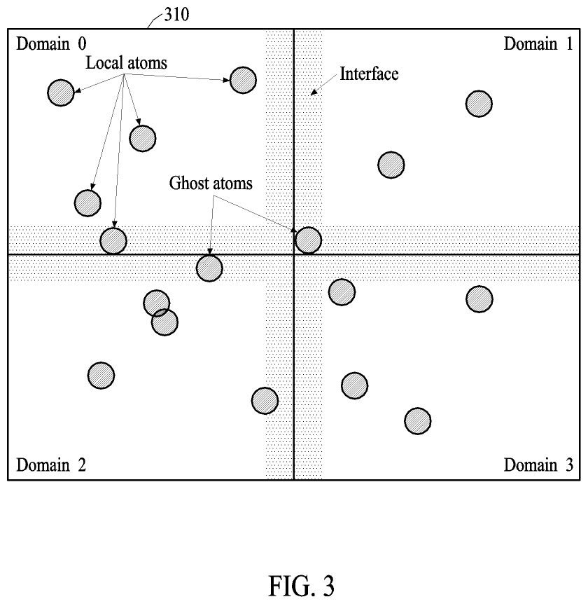

FIGS. 3 to 6 illustrate examples of compression schemes when MD simulation is executed.

Hereinafter, a procedure in which compression schemes are predetermined before runtime and the predetermined compression schemes are statically applied at runtime will be described using MD simulation as an example application.

MD simulation calculates dynamics for atoms by modeling potential or force generated between the atoms in a physical system to numerically solve Newton's equation of motion. Generally, the simulation may include three phases: 1) forward/reverse communication, 2) computation, and 3) modification. Among the phases of an MD simulation, in many cases, operations using a hardware core are mostly occupied by the computation phases, and data communication between cores (or processors, or electronic devices) may occur during the forward/reverse communication phases. During the forward/reverse communication phases, coordinate data and force data for modeled molecules may be moved between cores.

FIG. 3 illustrates an example of performing an MD simulation by dividing the simulation into a plurality of domains, according to one or more embodiments. The MD simulation may be performed based on a spatial-decomposition algorithm where the atoms/molecules are distributed amongst a plurality of spatial domains. For example, as the MD simulation has a significant amount of calculation, it may be difficult to perform the simulation with a single core or processor. Therefore, the simulation may be performed by a plurality of cores, a plurality of processors, or even a plurality of electronic devices (e.g., computers). A domain may be a unit divided when a work or a job is performed distributively by multiple cores, processors, or electronic devices. Four domains illustrated in FIG. 3 may be processed by four respective cores, processors, or electronic devices. The four domains illustrated in FIG. 3 are provided as an example for convenience of description, and thus examples are not limited thereto. Atoms included in each domain may be referred to as local atoms, and a region of each domain adjacent to another domain may be referred to as an interface. Although two spatial dimensions are shown in FIG. 3, in practice most simulations will be for three spatial dimensions.

Based on a domain 0 310 illustrated in FIG. 3, dynamics for the modeled atoms included in domain 0 310 may be calculated. For MD simulation, interaction between the atoms is calculated. For this purpose, atoms located at interfaces of adjacent domains may be considered, and such atoms may be referred to as ghost atoms. In the example of FIG. 3, although the ghost atoms belong to domains 1 and 2, respectively, the ghost atoms may be considered during the MD simulation for the domain 0 310, because the ghost atoms may affect the local atoms belonging to the domain 0 310. For pair operations between the atoms, data related to the ghost atoms may be transmitted to the core, processor, or electronic device for performing the MD simulation for the domain 0 310 from the adjacent domains. As the number of domains and atoms increases, the amount of data (e.g., related to ghost atoms) transmitted between domains and a communication time therefor may increase. However, as in the following description, it is possible to reduce an amount of moving data and thereby reduce communication time by compressing data for ghost atoms before transmitting the data for the ghost atoms.

For example, during a forward communication phase, it is possible to reduce an amount of communicated data by compressing coordinate data of the ghost atoms with a first predetermined compression scheme and transmitting the thus-compressed coordinate data. Alternatively, in the reverse communication phase, it is possible to effectively reduce an amount of communicated data by compressing force data of the ghost atoms with a second predetermined compression scheme and transmitting the thus-compressed force data.

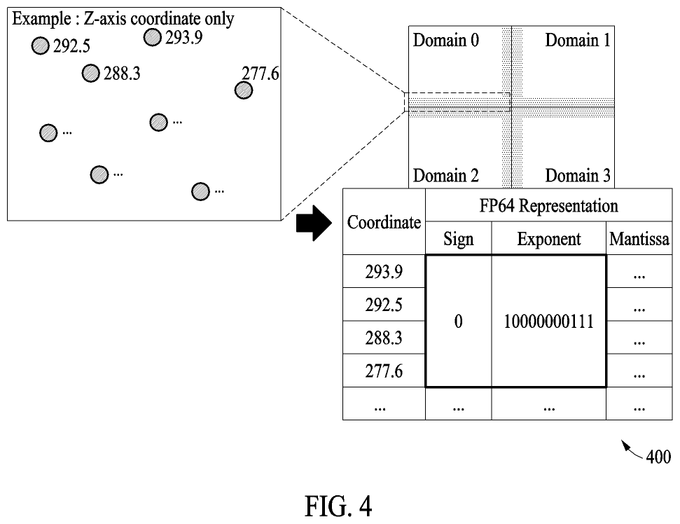

FIG. 4 illustrates an example of determining a compression scheme for coordinate data 400 of atoms in an MD simulation, according to one or more embodiments. Since atoms belonging to an interface of domain 0 illustrated in FIG. 4 correspond to ghost atoms of domain 2, coordinate data for the ghost atoms may be transmitted to a core, processor, or electronic device for performing MD simulation for domain 2.

Coordinate values of adjacent atoms may be similar. When the coordinate values have a same sign and exponent value, the coordinate values may be bundled and expressed in a block form. In the example of FIG. 4, a sign of coordinate values 293.9, 292.5, 288.3, and 277.6 is “0”, and an exponent thereof may be expressed as a block form of 10000000111. Alternatively, when similar coordinate values of adjacent atoms have a same exponent value, their exponent values may be bundled and expressed as a block form. In addition, coordinate values of the atoms may be quantized to a lower bit, with the effect of reducing an amount of data and also a communication time required by compression may be greater.

In the analysis procedure performed before runtime, in a phase of transmitting the coordinate data of ghost atoms, a compression scheme may be predetermined as block floating point-based compression based on a characteristic that the adjacent atoms have a same sign and exponent value or a same exponent value.

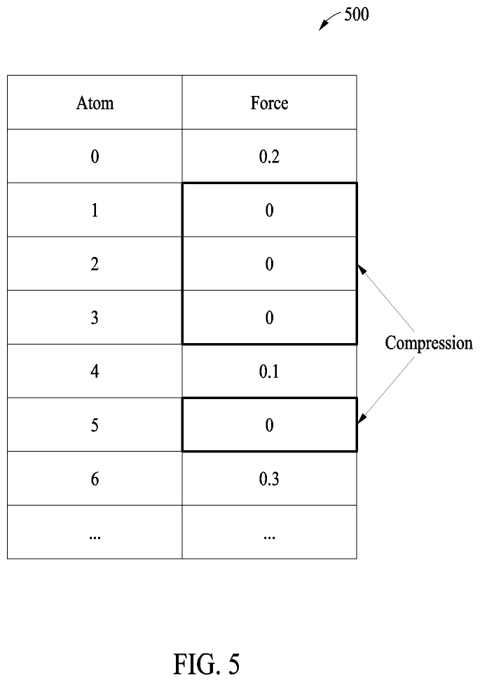

FIG. 5 illustrates an example of determining a compression scheme for force data of atoms to be communicated in an MD simulation, according to one or more embodiments. FIG. 5 shows examples 500 of force data of respective ghost atoms of one domain that is to be transmitted to a core, processor, or electronic device for performing MD simulation in a neighboring domain.

In some cases, many atoms may have overly small force values, for example, values of “0” (or near “0”) since forces of interaction between the other atoms may be offset. Compressing the values of “0” of the forces of multiple atoms may significantly reduce an amount of communicated data. In the example of FIG. 5, the force values of “0” of first, second, third, and fifth atoms may be compressed to reduce the amount of data.

In the analysis procedure before the runtime, for a phase of transmitting force data for the atoms, a zero-value-aware-based compression scheme may be predetermined (preselected) for that phase based on a characteristic that many atoms of that phase have force values of “0”.

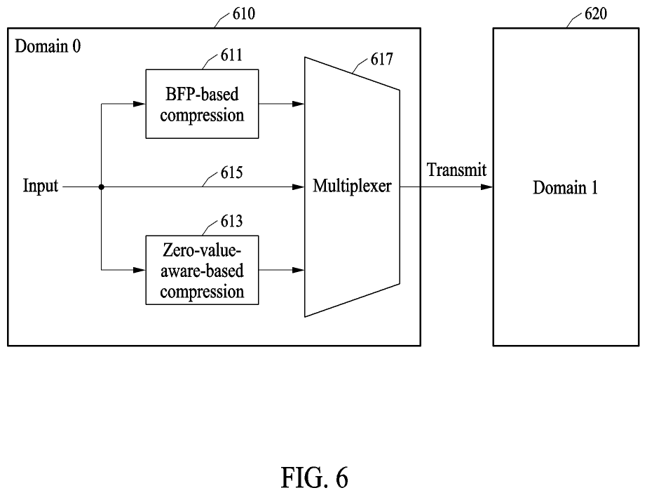

FIG. 6 illustrates an example of a hybrid compression scheme applied at runtime of an MD simulation, according to one or more embodiments. Specifically, FIG. 6 illustrates data transmitted from a domain 0 610 to a domain 1 620.

A predetermined compression scheme may be applied to the data before the data is transmitted to another domain. The compression scheme is not determined on-the-fly during the runtime by analyzing the data, but rather may be predetermined during the analysis procedure before runtime. For example, it may be predetermined that block floating point-based compression 611 is applied to the phase of transmitting the coordinate data for the atoms, and zero-value-aware-based compression 613 is applied to the phase of transmitting the force data of the atoms. In operation 615, when no compression scheme has been pre-selected for the data to be transmitted to another domain, the data may be transmitted without compression (alternatively, dynamic analysis and compression selection may be used). A multiplexer 617 may transmit the data processed by the hybrid compression scheme to another domain (e.g., the domain 1 620).

Hardware for applying the hybrid compression scheme illustrated in FIG. 6 may be implemented as hardware having a small area compared to a processor. Because the analysis procedure may be applied before runtime, a compression scheme to be applied to each phase may be predetermined, and therefore it may not be necessary to search for a compression scheme on-the-fly during the runtime.

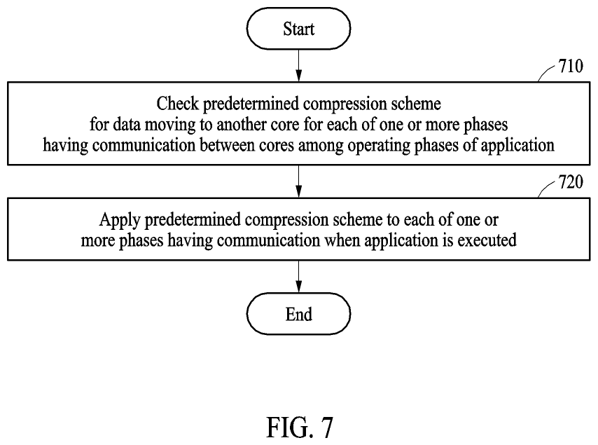

FIG. 7 illustrates an example of a method of operating an electronic device, according to one or more embodiments. In the example of FIG. 7, operations may or may not be performed sequentially. For example, the order of the operations may change, and the operations may be performed in parallel. Operations 710 and 720 may be performed by any one or any combination of components of an electronic device.

In operation 710, for each of one or more phases of an application having communication between cores among operating phases of the application to be executed in the electronic device, the electronic device checks for an associated predetermined compression scheme for data movement of the application from a source core to another (destination) core through communication of the corresponding phase. Such a compression scheme may have been pre-associated with the communication phase based on a pre-runtime identification of a dominant data pattern of the corresponding phase based on an analysis of the communication phase's communicated data. The other (destination) core and the reference (source) core that compresses and transmits the data may be located in a same processor, in different processors, or in processors in different electronic devices.

The application may be any application that executes in parallel on multiple cores, and the application may include, for example, any one or any combination of an MD simulation, training and/or inference of artificial intelligence, supercomputer-based processing, or the like. When the application is an MD simulation, a compression scheme for coordinate data of atoms moving from one core to another core may be predetermined as the block floating point-based compression 611, and a compression scheme for force data of atoms moving from one core to another core may be predetermined as the zero-value-aware-based compression 613.

In operation 720, the electronic device applies the predetermined compression scheme to each of the one or more phases having communication when the application is executed. The electronic device may statically apply the predetermined compression scheme without changing the compression scheme for the data moving to the other core when the application is executed. For example, information mapping compression schemes selected by the pre-execution analysis and identification of the application's data communication patterns to the respective communication phases may be incorporated into the application (e.g., at compile time), may be dynamically linked at runtime (e.g., by a separately compiled dynamically linked library), by a table mapping schemes to phases which is referenced by calls associated with the communication phases, by instructions added to the application when the application is re-compiled using the associations as compiler hints or instructions, by a module of the application that abstracts the communication of inter-core data, etc.

The electronic device includes one or more processors each including a plurality of cores for performing operations of the application. The one or more processors may include one or any combination of a central processing unit (CPU), a graphics processing unit (GPU), and a neural processing unit (NPU).

The descriptions provided with reference to FIGS. 1 to 6 may apply to the operations shown in FIG. 7.

The computing apparatuses, the electronic devices, processors, memories, and other apparatuses, devices, and components described herein with respect to FIGS. 1-7 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIM D) multiprocessing, multiple-instruction single-data (MISD) multiprocessing, and multiple-instruction multiple-data (MIMD) multiprocessing.

The methods illustrated in FIGS. 1-7 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An electronic device comprising:
cores of one or more processors;
one or more memories storing instructions configured to, when executed by the cores, configure the cores to:
perform operations of an application executed on the electronic device, the operations including communication phases that communicate data between the cores, wherein the application comprises, prior to execution of the application on the electronic device, predetermined information associating the communication phases with respective compression schemes, and
apply the compression schemes corresponding to the communication phases according to the predetermined information to compress the data of the communication phases that is exchanged between the cores when executing the application.

2. The electronic device of claim 1, wherein the predetermined information generated, before the execution of the application, based on determining dominant data patterns of the communication phases while analyzing the application before the application is executed.

3. The electronic device of claim 1, wherein the cores comprise a source core and a destination core located in a same processor, in different processors, or in processors comprised in different electronic devices.

4. The electronic device of claim 1, wherein the application comprises a molecular dynamics (MD) simulation, training of and/or inference by an artificial intelligence module, supercomputer-based processing, and/or a multi-node task.

5. The electronic device of claim 1, wherein the application performs an MD simulation, wherein a first of the compression schemes is associated, by the predetermined information, with communication phases that communicate coordinate data of simulated atoms between the cores, the first compression scheme comprising a block floating point-based compression scheme, and wherein a second of the compression schemes is associated, by the predetermined information, with communication phases that communicate data of force data of the simulated atoms between the cores, the second compression scheme comprising a zero-value-aware-based compression scheme.

6. The electronic device of claim 1, wherein the one or more processors comprise any one or any combination of: a central processing unit (CPU), a graphics processing unit (GPU), or a neural processing unit (NPU).

7. The electronic device of claim 1, wherein the predetermined information indicates which communication phases are associated with which compression schemes.

8. The electronic device of claim 1, wherein the predetermined information is generated by, prior to the executing of the application on the electronic device, analyzing data communicated between the communication phases to identify patterns of the data.

9. A method comprising:
executing an application in parallel on cores of an electronic device, including executing communication phases on the cores, wherein, prior to beginning the executing of the application, the communication phases are associated with compression schemes, and wherein which communication phases are associated with which compression schemes is determined, prior to the beginning the executing of the application, by analyzing data patterns of the communication phases and based thereon associating the communication schemes with the communication phases; and
when executing each of the communication phases, checking, for each of the communication phases, for a compression scheme pre-associated therewith, and based thereon, communicating data of the communication phases between the cores using compression and decompression of the pre-associated compression schemes.

10. The method of claim 9, wherein an association between a compression scheme and a communication phase is predetermined based on determining a dominant data pattern of the communication phase in an analysis procedure performed for the application before the executing of the application.

11. The method of claim 9, wherein the cores perform the compression and decompression and are located either in a same processor or in different processors.

12. The method of claim 9, wherein the electronic device comprises two computing devices, the computing devices comprising respective processors, the processors each comprising a respective one of the cores.

13. The method of claim 9, wherein a second electronic device comprises a second core,
wherein the executing the application further comprises executing the application on the second core, and
when executing a communication phase on the second core, checking, for a compression scheme pre-associated with the communication phase executing on the second core, and based thereon, communicating data of the communication phase executing on the second core between the second core and a core of the electronic device using compression and decompression of the pre-associated compression schemes.

14. The method of claim 9, wherein the application comprises a molecular dynamics (MD) simulation.

15. The method of claim 9, wherein the application trains or implements a machine learning model.

16. A non-transitory computer-readable storage medium storing instructions that, when executed by a processor, cause the processor to perform the method of claim 9.

17. A method comprising:
executing an application in parallel on two cores, the application comprising operation phases and communication phases, the operation phases generating data, the communication phases exchanging the data between the cores, the application further comprising, prior to execution of the application, association information comprising first association information associating first of the communication phases with a first compression scheme and second association information associating second of the communication phases with a second compression scheme;
when executing a first communication phase, based on the first association information, using the first compression scheme to compress and decompress data exchanged between the cores by the first communication phase; and
when executing a second communication phase, based on the second association information, using the second compression scheme to compress and decompress data exchanged between the cores by the second communication phase.

18. The method of claim 17, further comprising, before executing the application on the two cores:
identifying patterns of data associated with the communication phases; and
generating the association information based on the identifying of the patterns.

19. The method of claim 18, wherein a first identified pattern of data corresponds to the first communication phases and a second identified pattern of data corresponds to the second communication phases.

20. The method of claim 18, wherein the identifying comprises determining a most frequent or common pattern of data associated with a communication phase and wherein the generating the association information comprises associating a compression scheme with the communication phase based on the pattern of data determined to be most frequent or most common.
